(19) United States
(12) Patent Application Publication
(10) Pub. No.: US 2020/0287065 A1
(43) Pub. Date: Sep. 10, 2020

(54) Dopant enhanced solar cell and method of manufacturing thereof

(71) Applicant: Nederlandse Organisatie voor toegepast-natuurwetenschappelijk Onderzoek TNO, The Hague (NL)

(72) Inventors: Maciej Krzyszto Stodolny, Petten (NL); John Anker, Petten (NL); Martien Koppes, Petten (NL); Ingrid Gerdina Romijn, Petten (NL); Lambert Johan Geerligs, Petten (NL)

(73) Assignee: Nederlandse Organisatie voor toegepast-natuurwetenschappelijk Onderzoek TNO, The Hague (NL)

(21) Appl. No.: 16/646,175

(22) PCT Filed: Sep. 24, 2018
(86) PCT No.: PCT/NL2018/050632

§ 371 Date: Mar. 11, 2020

(30) Foreign Application Priority Data
Sep. 22, 2017 (NL) 2019614

(51) Int. Cl. H01L 31/0224; H01L 31/18

(52) U.S. Cl. CPC H01L 31/02245; H01L 31/1864; H01L 31/182

(57) ABSTRACT

The present invention relates to a dopant enhanced silicon based solar cell and method of manufacturing thereof. The solar cell includes on a surface of the silicon substrate a layer stack including a thin oxide layer and a polysilicon layer, the thin oxide layer being arranged as a tunnel oxide layer in-between the surface of the substrate and the polysilicon layer. The solar cell is provided with fire-through metal contacts arranged on the layer stack locally penetrating into the polysilicon layer. The silicon substrate is provided at the side of the surface with a dopant species that creates a dopant profile of a first conductivity type in the silicon substrate. The dopant profile in the silicon substrate has a maximal dopant level between about 1×10⁺¹⁸ and about 3×10⁺¹⁹ atoms/cm³ and a depth of at least 200 nm within the substrate to a dopant atom level of 1×10⁺¹⁷ atoms/cm³.

### FIELD OF THE INVENTION

The present invention relates to a dopant enhanced solar cell based on a silicon substrate and method of manufacturing thereof.

### BACKGROUND ART

Doped polysilicon/thin oxide layer stacks (hereafter doped polySi/oxide stacks) can be used to form very high quality carrier-selective junctions for crystalline silicon cells, resulting in potentially very high cell efficiency. For contacting of the doped polysilicon (polySi) layer there are various options, such as fire-through (FT) paste, non-fire-through (NFT) paste, evaporated (PVD) metal, plated contacts and transparent conductive oxide (TCO).

A limiting effect on cell efficiency are recombination losses, which can occur at various locations throughout the stack, whereby current is lost between the solar power collecting surface and the contact.

Most preferred and therefore dominantly used contacts are FT contacts, i.e. contacts based on a FT paste, due to their low-cost and established technology. A downside of FT contacts, however, is that their application on doped polySi/oxide stacks often results in increased recombination at the location of the interface between the wafer and tunnel oxide layer, lowering cell efficiency. As a result, it is highly desirable to establish how FT contacts can be applied on doped polySi/oxide stacks with very limited resulting recombination at the location of the interface.

One known solution has been disclosed by Ciftpinar et al. in Proceedings of the 7th International Conference on Crystalline Silicon Photovoltaics (SiPV2017, April 2017, Freiburg, Germany), to be published in Energy Procedia, which is to use relatively thick polySi. However, the use of relatively thick polySi is disadvantageous for process cost, and for cell efficiency from the point of view of optical free carrier absorption losses.

It is an object of the present invention to provide an efficient solar cell structure based on a silicon substrate and method of manufacturing thereof with, in comparison to the prior art, limited recombination of a FT metal contact.

### SUMMARY OF THE INVENTION

According to the present invention, a solar cell as defined above is provided, in which the solar cell based on a silicon substrate, comprises on a surface of the silicon substrate a layer stack comprising a thin oxide layer and a polysilicon layer, the silicon dioxide layer being arranged as a tunnel oxide layer inbetween said surface of the silicon substrate and the polysilicon layer; the solar cell being provided with metal contacts arranged on the layer stack locally penetrating into the polysilicon layer; wherein the silicon substrate is provided at the side of said surface with a dopant species that creates a dopant profile of a first dopant species of a first conductivity type in the silicon substrate, and the dopant profile of the first dopant species in the silicon substrate has a maximal dopant level between about 1×10⁺¹⁸ and about 3×10⁺¹⁹ atoms/cm³ and at a depth of at least 200 nm within the silicon substrate has a dopant atom level of 1×10⁺¹⁷ atoms/cm³.

The presence of this doping profile in the silicon substrate limits the recombination at the location of the metal contacts without requiring high polySi layer thicknesses and thus positively affects efficiency of the solar cell.

In a further embodiment the polysilicon layer is provided with a second dopant species of the first conductivity type having a dopant level in the polysilicon layer above the maximal dopant level in the silicon substrate. As a result, a positive differential exists across the thin oxide (or tunnel oxide) layer, creating “pull”, which ensures good transmission of charge carriers of the first conductivity type across the tunnel oxide layer from the silicon substrate towards the polysilicon layer. As a result, the efficiency of the solar cell is increased.

Here, the maximal dopant level in the silicon substrate as described above, is to be measured at about 15 nm below the interface of the thin oxide layer and the substrate. The dopant level is determined by analytical method and equipment as known in the art.

According to a further embodiment the depth of the dopant profile to the dopant level of 10⁺¹⁷ atoms/cm⁺³ is between about 200 nm and about 1 μm. The thinner the polysilicon layer, the more dopant profile tail is required to obtain a solar cell in which the recombination is sufficiently limited. However, once the tail becomes too long or too highly doped, the positive effect limiting recombination is lost.

In an embodiment, the metal contacts are based on a fire-through metal paste. It is generally accepted that FT contacting technology is a well-established and low-cost technology, thus use of such contacts in the present invention provide better compatibility with present industrial manufacturing and lower costs. Additional advantage of FT contact technology is that it includes application of hydrogen-rich dielectric coating, which could be selected from PECVD SiNₓ:H and AL₂O₃, and so-called “firing”, which results in hydrogenation of the polySi/oxide stack, thereby favourably increasing the passivation performance of the layer stack. Due to the specific doping profile of the layer stack including dopant profile tail, the application of FT contacts on these doped polySi/oxide stacks only has very limited resulting recombination at the location of the interface, also when at some points metal is in direct contact with the silicon wafer (i.e., even without separating layer of interfacial oxide or polySi between the metal and wafer). Thus the combination of the doping profile throughout the stack and the use of FT contacts results in a desirably efficient solar cell with low manufacturing cost.

Furthermore, in an embodiment the dopant profile in the silicon substrate as function of depth in the silicon substrate can be without being bound to any specific theory described to a good approximation by a Gaussian profile with the maximal dopant level positioned in the silicon substrate at a first distance from the interface of the silicon substrate and the thin oxide layer, and the maximal dopant level of the dopant species in the silicon substrate is lower than an average dopant level of the dopant species in the polysilicon layer by a factor of three or more. The average dopant level is determined as an average over the thickness of the polysilicon layer.

In some embodiments, the dopant species in the polysilicon layer may be identical to the dopant species in the silicon substrate. Alternatively, the dopant species in the polysilicon layer and in the silicon substrate may be different from each other. What is further claimed is a method for manufacturing a solar cell based on a silicon substrate as described above.

### BRIEF DESCRIPTION OF THE DRAWINGS

The present invention will be discussed in more detail below, with reference to the attached drawings, in which:

FIG. 1 depicts a cross-section of a polysilicon passivated solar cell with a metal contact.

FIG. 2 shows a doping profile of a solar cell according to an embodiment.

FIGS. 3A, 3B and 3C show respective flow diagrams for manufacturing a silicon substrate based solar cell with a polysilicon passivated contact stack and a metal contact according to an embodiment.

### DESCRIPTION OF EMBODIMENTS

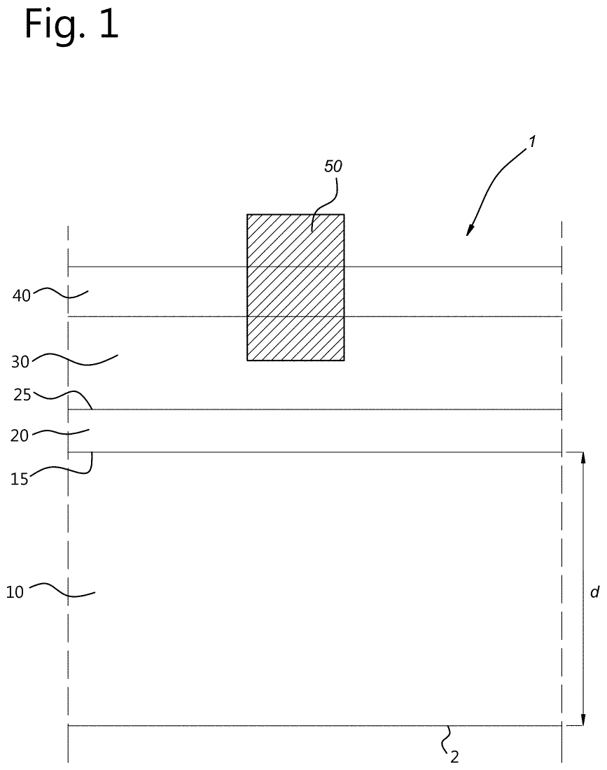

FIG. 1 depicts a cross-section of a polysilicon passivated solar cell with a metal contact. The solar cell layer stack 1 comprises a silicon substrate 10, a tunnel oxide layer 20, a polysilicon layer 30, an dielectric coating layer 40 and a metal contact 50.

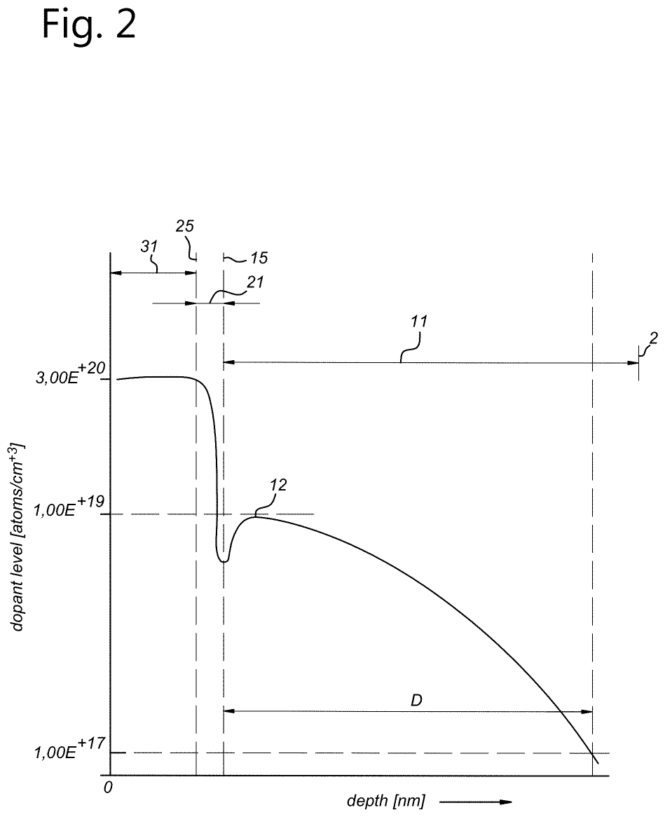

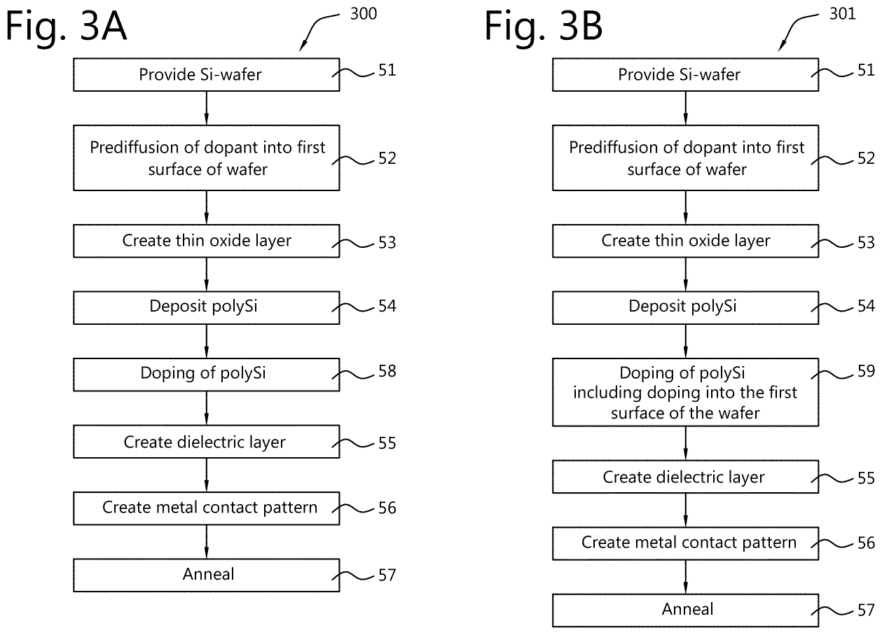

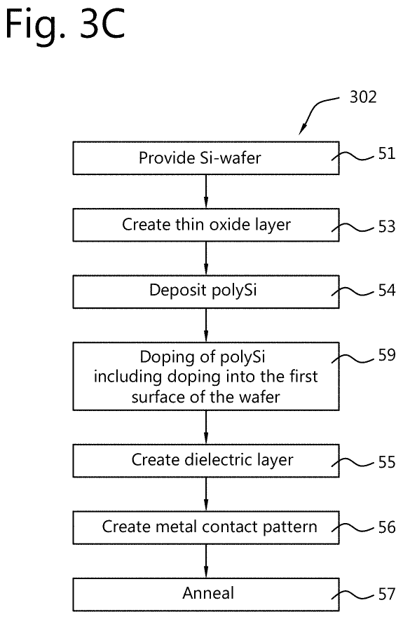

The silicon substrate 10 has a front surface 2, intended for facing the Sun when in use, and a rear surface onto which a tunnel oxide layer 20 has been created. A thin oxide is commonly used as tunnel oxide material. The layer has a minimum thickness of about 1 nm, 3 atomic layers, and is maximised at around 5 nm. The silicon substrate is a doped silicon wafer, which has been doped in a pre-diffusion step and/or during doping of polySi resulting in the claimed dopant profile which is discussed with reference to FIGS. 2 and 3. The thin oxide layer may be a silicon oxide or metal oxide and may contain other additional elements such as nitrogen. The thin oxide layer may in actual effect not be a perfect tunnel barrier, as it can e.g. contain imperfections such as pinholes, which can result in other charge carrier transport mechanisms (such as drift, diffusion) dominating over tunneling.

On top of the thin oxide layer 20, the polysilicon layer 30 has been deposited, such that the surface interface of the thin oxide layer and the silicon substrate 15 comprises the front surface of the thin oxide layer and the surface interface of the tunnel oxide layer and the polysilicon layer 25 comprises the rear surface of the thin oxide layer. The polysilicon layer is a doped layer, preferably of the n-type, created by a phosphorus dopant. However, a p-type dopant species such as boron dopant may also be used, resulting in a p-type doped layer. Further, the polysilicon layer may contain other additional elements such as carbon or oxygen atoms.

The anti-reflection layer 40, usually an anti-reflective coating, covers the free surface of the polysilicon layer. A metal contact 50 has been applied on the solar cell layer stack 1 such that it protrudes the anti-reflection layer 40 and part of the polysilicon layer 30. The metal contact is preferably a fire-through paste contact, since it is a low cost contact that can be applied using well established manufacturing technology, thereby contributing to the affordability of efficient solar cells. A FT metal contact may locally fully penetrate the polySi or the polySi as well as the thin oxide, resulting in local contacts between the metal and the Si substrate. This may enhance the intimate electrical contact between the FT contact and the substrate for charge carrier collection, improving the series resistance of the cell.

FIG. 2 shows a doping profile of a solar cell according to an embodiment. The doping profile is defined as the dopant level in atoms/cm′ over the depth of the solar cell layer stack, from the polysilicon-anti-reflective layer interface towards the front surface 2. The profile can be split into three characterising sections, which correspond to layers of the solar cell stack presented in FIG. 1.

The first section represents the dopant profile in the polysilicon layer 31, which is delimited by the interface 25 of the silicon dioxide layer and the polysilicon layer. The dopant level of the polysilicon layer is between about 1×10⁺²⁰ and about 3×10⁺²⁰ atoms/cm⁺³ and may be p- or n-type, depending on the base conductivity type of the silicon substrate.

The second section represents the dopant profile around and within the tunnel oxide layer 21, which is delimited on the first side by the interface 25 of the thin oxide layer and the polysilicon layer and on the second side by the interface 15 of the thin oxide layer and the silicon substrate. In this second section, the profile comprises a drop with inflection point, in the profile between the doped polysilicon and the profile in the silicon substrate, substantially across the thin oxide layer.

It should be noted that the dopant profile around and within the thin oxide layer is normally an laterally averaged quantity, as it is known that e.g. pinholes in the thin oxide can result in microscopic local lateral variations of the dopant concentration. A measurement method such as electrochemical profiling (ECV) or secondary ion mass spectrometry (SIMS) will show this laterally averaged quantity.

The third section represents the dopant profile within the silicon substrate 11, also called tail. The profile of the tail comprises a tail depth D of at least 200 nm, optionally up to about 1000 nm, as measured from the polysilicon interface up to a depth position where the dopant level is 1×10⁺¹⁷ atoms/cm³, and a peak dopant level in the silicon substrate of between 1×10⁺¹⁸ and 3×10⁺¹⁹ atoms/cm³. Thus the maximum, i.e., the peak dopant level, 12 is at least a factor three lower than the average dopant level in the polysilicon layer. The peak dopant level 12 should be determined sufficiently far away from the interface 15, e.g. 15 nm, to avoid smearing effects from measurement artefacts. For thinner layers of polysilicon the tail depth D is preferably larger than 200 nm to reach the desired effect of limited recombination at the interface 15.

As previously described, the dopant used is either be p-type or n-type, although n-type may be preferred. Obtaining the desired and required dopant profile tail may be an easier controllable process in n-type polysilicon.

FIGS. 3A, 3B and 3C show respective flow diagrams 300, 301 and 302 for manufacturing a polysilicon passivated contact stack with a metal contact according to embodiments of the invention.

In FIG. 3A, the manufacturing 300 starts with 51 the provision of a silicon substrate 10, also called wafer. Then a first doping step is performed through pre-diffusion 52 of a dopant species into a first surface of the silicon substrate for example by elevated temperature solid source diffusion whereby a dopant glass layer is applied followed by annealing and subsequent removal of the glass layer. By annealing at a pre-set temperature for a predetermined amount of time the first dopant species diffuses into the substrate such that the first dopant species profile meets the requirements set forth for the third section 11 presented in FIG. 2. Thus the dopant profile in the silicon substrate is created under such conditions that the dopant profile has a maximal dopant level between about 1×10⁺¹⁸ and about 3×10⁺¹⁹ atoms/cm³ and a depth of at least 200 nm to dopant atom level of 1×10⁺¹⁷ atoms/cm³. Alternative processes that may be used for the creation of the dopant profile in the silicon substrate are: elevated temperature gas source diffusion of dopant or ion-implantation of dopant.

Further, this step may comprise a partial etch back of the silicon substrate after doping before later provision of the layer stack, to ensure the dopant profile indeed has a maximum concentration between 1×10⁺¹⁸ and about 3×10⁺¹⁹ atoms/cm³ and a depth of at least 200 nm to dopant atom level of 1×10⁺¹⁷ atoms/cm³.

In a next step 53 a thin oxide layer is created on the same surface the pre-diffusion step was previously performed on. The thin oxide layer is created by a process selected from a group comprising atomic layer deposition, high temperature oxidation or wet chemical oxidation, ozone oxidation, plasma oxidation, and consists of at least silicon oxide.

The following step 54 comprises the deposition of a polysilicon (polySi), using a chemical or physical vapour deposition process. This polysilicon layer is then doped 58 in a second doping step, using the same dopant as the first dopant species used for doping the silicon substrate, whereby the dopant profile as described for the first section 31 of FIG. 2 is created by a process selected from a group comprising co-deposition, ion-implantation, gas source diffusion or solid source diffusion. The process may include an anneal (e.g. implant activation anneal).

Next, a dielectric coating layer, preferably hydrogen-rich, is created 55 on the surface of the polysilicon layer facing away from the silicon substrate.

This step is followed by 56 creating on the dielectric coating layer a metal contact pattern which locally penetrates into the polysilicon layer. The metal contacts are created from a pattern of fire-through metal paste on the layer stack by a fire-through annealing step 57. The fire-through annealing step is carried out under conditions such that the metal contacts do not penetrate into the silicon dioxide layer or the silicon substrate. Alternatively, the fire-through annealing step results in metal contacts locally penetrating the polySi or the thin oxide and touching the silicon substrate, resulting in local direct contacts between the metal and the silicon substrate. Furthermore, the fire-through annealing step 57 is carried out such that the dopant profile in the silicon substrate is not significantly affected meaning that further diffusion of the dopant species in the silicon substrate is negligible.

Alternatively, the manufacturing process 301 may follow the steps shown in FIG. 3B. In this process, the pre-diffusion of a first species dopant 52 into a first surface of the silicon substrate only results in an initial doping profile within the substrate. The second doping step 59 is changed such that the polysilicon layer is doped, using the same dopant species as used for doping the silicon substrate, whereby the dopant also penetrates into the first surface of the silicon substrate.

In a further alternative manufacturing process 302, shown in FIG. 3C, no first doping step is used. Instead, the doping profile meeting the requirements discussed under FIG. 2 is created in a single step 59, whereby doping of the polysilicon layer also includes doping into the first surface of the silicon substrate.

In each of the manufacturing processes 300, 301, 302 the dopant species profile in the silicon substrate is tuned to the meet the requirements set forth as above at the stage before metallization, e.g. after later process steps to dope and anneal the polySi layer.

The invention has been described with reference to the preferred embodiments. Although the dopant enhanced solar cell is described as having FT contacts, the invention is not limited thereto. The invented dopant profile is likely to provide a significant advantage or improvement for solar cells having contacts applied with technologies other than FT, firing through.

Also, although the invention has been described with respect to back side contacts of the solar cell, the invention can also be beneficially applied to contacts on a front side of a solar cell.

Further obvious modifications and alterations will occur to others upon reading and understanding the preceding detailed description. It is intended that the invention be construed as including all such modifications and alterations insofar as they come within the scope of the appended claims.

1. A solar cell based on a silicon substrate, comprising on a surface of the silicon substrate a layer stack comprising a thin oxide layer and a polysilicon layer, the silicon dioxide layer being arranged as a tunnel oxide layer in-between said surface of the silicon substrate and the polysilicon layer; the solar cell being provided with metal contacts arranged on the layer stack locally penetrating into the polysilicon layer;
wherein the silicon substrate is provided at the side of said surface with a dopant species that creates a dopant profile of a first dopant species of a first conductivity type in the silicon substrate, and the dopant profile of the first dopant species in the silicon substrate has a maximal dopant level between about 1×10⁺¹⁸ and about 3×10⁺¹⁹ atoms/cm³ and at a depth of at least 200 nm within the silicon substrate has a dopant atom level of 1×10⁺¹⁷ atoms/cm³,
wherein the metal contacts are fire-through metal contacts that locally fully penetrate the polysilicon as well as the thin oxide, resulting in local contacts between the metal and the silicon substrate, such that the metal contacts are locally in direct contact with the silicon substrate.

2. The solar cell according to claim 1, wherein the polysilicon layer is provided with a second dopant species of the first conductivity type having a dopant level in the polysilicon layer above the maximal dopant level in the silicon substrate.

3. The solar cell according to claim 2, wherein the dopant level in the polysilicon layer is between about 1×10⁺²⁰ and about 3×10⁺²⁰ atoms/cm³.

4. The solar cell according to claim 2, wherein the dopant level has a decreasing gradient between the polysilicon layer and the silicon substrate, across the silicon dioxide layer.

5. The solar cell according to claim 1, wherein the maximal dopant level in the silicon substrate is measured at about 50 nm below the interface of the silicon dioxide layer and the substrate.

6. The solar cell according to claim 1, wherein the depth of the dopant profile to the dopant level of 10⁺¹⁷ atoms/cm³ is between about 200 nm and about 1 μm.

7. The solar cell according to claim 1, wherein the layer stack further comprises an hydrogen-rich dielectric coating layer on the surface of the polysilicon layer facing away from the silicon substrate.

8. The solar cell according to claim 7, wherein the hydrogen rich coating layer is selected from a group comprising a SiNₓ:H layer and an Al₂O₃ layer.

9. The solar cell according to claim 1, wherein the metal contacts are fire-through contacts, which penetrate during the firing step through a dielectric coating layer and into the polysilicon layer and are based on a fire-through metal paste.

10. (canceled)

11. The solar cell according to claim 4, wherein the dopant profile in the silicon substrate as function of depth in the silicon substrate is described by a Gaussian profile with the maximal dopant level positioned in the silicon substrate at a first distance from the interface of the silicon substrate and the thin oxide layer, and the maximal dopant level of the first dopant species in the silicon substrate is lower than an average dopant level of the second dopant species in the polysilicon layer by a factor of three or more.

12. The solar cell according to claim 2, wherein the second dopant species in the polysilicon layer is identical to the first dopant species in the silicon substrate.

13. The solar cell according to claim 1, wherein the first conductivity type is n-type, and the first dopant species and second dopant species are each selected from a group comprising P, As, and Sb.

14. The solar cell according to claim 1, wherein the polysilicon layer has a thickness between about 20 and about 300 nm.

15. The solar cell according to claim 1, wherein the thin oxide layer has a thickness of about 5 nm or less but at least three atomic layers.

16. A method for manufacturing a solar cell based on a silicon substrate, comprising:
providing the silicon substrate;
creating on said surface a layer stack comprising:
creating a thin oxide layer on a surface of the silicon substrate,
and creating a doped polysilicon layer on the thin oxide layer, the doped polysilicon layer containing a dopant species of a first conductivity type,
such that the layer stack comprises the thin oxide layer arranged as a tunnel oxide layer in-between said surface of the silicon substrate and the doped polysilicon layer;
the method further comprising:
creating in a surface of the silicon substrate a dopant profile of a dopant species of the first conductivity type,
wherein the creation of the dopant profile in the silicon substrate is done either in a first process preceding the creation of the doped polysilicon layer or in a second process simultaneously during the creation of the doped polysilicon layer, and wherein the dopant profile in the silicon substrate is created under such conditions that the dopant profile of the dopant species of the first conductivity type in the silicon substrate has a maximal dopant level between about 1×10⁺¹⁸ and about 3×10⁺¹⁹ atoms/cm³ and at a depth of at least 200 nm within the silicon substrate has a dopant atom level of about 1×10⁺¹⁷ atoms/cm³,
wherein the method comprises
creating on the layer stack metal contacts that locally penetrate into at least the polysilicon layer, wherein the metal contacts are created from a pattern of fire-through metal paste on the layer stack by a fire-through annealing step, such that the metal contacts are fire-through metal contacts that locally fully penetrate the polysilicon as well as the thin oxide, resulting in local contacts between the metal and the silicon substrate, and the metal contacts are locally in direct contact with the silicon substrate.

17. The method according to claim 16, further comprising:
providing a dopant level of the dopant species of the first conductivity type in the polysilicon layer under such conditions that a dopant level in the polysilicon layer is above the maximal dopant level in the silicon substrate.

18. The method according to claim 16, wherein the maximal dopant level and the dopant atom level at the depth of at least 200 nm are obtained after completion of the doping and activation of the doped polysilicon layer.

19. The method according to claim 16, wherein the thin oxide layer is created by a process selected from a group comprising atomic layer deposition, high temperature oxidation, wet chemical oxidation, plasma oxidation or a reaction with ozone.

20. The method according to claim 16, wherein the first process for creating the dopant profile in the silicon substrate is a process selected from a group comprising:
elevated temperature solid source diffusion of the dopant species, elevated temperature gas source diffusion of the dopant species, ion-implantation of the dopant species.

21. The method according to claim 16, further comprising: preceding the creation of the dopant profile in the silicon substrate, creating in the layer stack an anti-reflective layer on the surface of the polysilicon layer that is facing away from the silicon substrate, wherein the polysilicon layer is created by a chemical or physical vapour deposition process, and the dopant profile of the second doping species in the polysilicon layer is created by a process selected from a group comprising:
co-deposition of the dopant species with the polysilicon, in-situ doping of the polysilicon, ion-implantation of the dopant species, gas source diffusion of the dopant species.

22. The method according to claim 18, further comprising a partial etch back of the silicon substrate preceding the creation of the layer stack.

23.-25. (canceled)

26. The method according to claim 16, further comprising: preceding the creation of the dopant profile in the silicon substrate, creating in the layer stack an anti-reflective layer on the surface of the polysilicon layer that is facing away from the silicon substrate
